(19) United States
(12) Patent Application Publication
(10) Pub. No.: US 2023/0398881 A1
(43) Pub. Date: Dec. 14, 2023

(54) METHOD AND CONTROL DEVICE FOR OPERATING A CHARGER FOR ELECTRICALLY DRIVEN VEHICLES AND CHARGER

(71) Applicants: Dr. Ing. h.c. F. Porsche Aktiengesellschaft, Stuttgart (DE); ads-tec Energy GmbH, Nuertingen (DE)

(72) Inventors: Raoul Heyne, Wiernsheim (DE); Holger Ochs, Moetzingen (DE); Daniel Ziegler, Reutlingen (DE); Thorsten Ochs, Weil der Stadt (DE); Simon Bareiss, Rudersberg (DE)

(21) Appl. No.: 18/207,727

(22) Filed: Jun. 9, 2023

(30) Foreign Application Priority Data
Jun. 10, 2022 (DE) 10 2022 114 728.2
Aug. 18, 2022 (DE) 10 2022 120 836.2

(51) Int. Cl. B60L 53/10; G01R 31/52; B60L 53/16

(52) U.S. Cl. CPC B60L 53/11; G01R 31/52; B60L 53/16; B60L 53/60

(57) ABSTRACT

A method is provided for operating a bidirectional charger (1) for DC charging of electric vehicles. The charger (10) has a charging terminal (11) for connecting an electrically driven vehicle and at least one power electronics unit (12) for providing defined charging current and defined charging voltage at the charging terminal (11). The power electronics unit (12) is subjected to a self-test voltage of at least the maximum charging voltage of the charger (10) at defined time intervals for a defined time for performing a self-test when there is no vehicle at the charging terminal (11). A check then is performed to ascertain whether a short circuit or defect is formed at the power electronics unit (12). The charging terminal (11) is enabled for charging a vehicle if no short circuit is found and the charging terminal is blocked for charging a vehicle when a short circuit is established.

### CROSS REFERENCE TO RELATED APPLICATIONS

This application claims priority on German Patent Application No 10 2022 114 728.2.6 filed Jun. 10, 2022 and German Patent Application No 10 2022 120 836.2.2 filed Aug. 18, 2022, the entire disclosures of which are incorporated herein by reference.

### BACKGROUND

### Field of the Invention

The invention relates to a method for operating a bidirectional charger for DC charging of electrically driven vehicles. Furthermore, the invention relates to a control device of a bidirectional charger for DC charging electrically driven vehicles and to a charger.

### Related Art

A known charger for electrically driven vehicles has at least one charging terminal that can be coupled to an electrically driven vehicle for charging the vehicle. At least one power electronics unit interacts with the charging terminal of the charger. The or each power electronics unit interacting with the respective charging terminal is designed to provide a defined charging current and a defined charging voltage at the respective charging terminal for charging the electrically driven vehicle.

So-called AC charging or so-called DC charging can be used for charging an electrically driven vehicle at a charger. DC charging is used to charge the traction battery of an electrically driven vehicle within a short time with a high charging power.

Chargers for DC charging of the traction battery of an electrically driven vehicle can be unidirectional chargers or bidirectional chargers. Bidirectional chargers enable the electrical energy stored in the traction battery of an electrically driven vehicle to be fed back into an electrical power supply system to support the electrical power supply system. Such bidirectional chargers are gaining increasing importance.

The traction battery of an electrically driven vehicle that is connected to a charging terminal of a bidirectional charger for DC charging can be damaged if a short circuit is formed at a power electronics unit that interacts with a charging terminal. Thus, the electrically driven vehicle requires a visit to a workshop.

There is a need to avoid a risk of damage to a connected vehicle as a result of a short circuit of a power electronics unit in the case of bidirectional chargers for DC charging of electrically driven vehicles.

US 2013/0278273 A1 discloses a method and a device for identifying a short circuit at a charger for electrically driven vehicles. To identify a short circuit, a test voltage is applied to a charging cable. This test voltage is increased stepwise up to a maximum voltage value. A check is performed to ascertain whether a short circuit is formed at the charging cable or a contact means connected to the charging cable.

U.S. Pat. No. 11,376,983 B2 and DE 10 2019 117 375 A1 disclose further chargers for DC charging of electrically driven vehicles. For example, U.S. Pat. No. 11,376,983 B2 discloses a charger with an insulation monitoring device that has at least two electrical measuring resistors each of which is connected to a charging line. Prior to each charging operation, an insulation test is performed by the insulation monitoring device both in an asymmetrical test mode and in a symmetrical test mode, for example by a bus shifting method.

WO 2022/008 640 A1 discloses a charger for an electrically driven vehicle.

WO 2015/036 063 A1 discloses an electrically driven vehicle having insulation monitoring for a high-voltage vehicle power supply system.

There is a need for a method for operating a bidirectional charger for DC charging electrically driven vehicles and for a control device for performing the method with which it is possible to prevent a risk of damage to the vehicle due to a short circuit at a power electronics unit of the charger that is connected to the vehicle for charging. There is further a need for a corresponding charger.

Accordingly, the invention is based on the object of providing an improved method and control device for operating a bidirectional charger for DC charging of electrically driven vehicles and a corresponding charger.

### SUMMARY OF THE INVENTION

According to the invention, the power electronics unit of the charging terminal is subjected to a self-test voltage when there is no vehicle connected to the charging terminal. The self-test is performed by applying at least the maximum charging voltage of the charger at defined time intervals for a defined self-test time period. In this case, a check is performed to ascertain whether a short circuit or defect is formed at the power electronics unit of the charging terminal. The charging terminal is enabled for charging a vehicle when it is established that no short circuit or defect is formed, and the charging terminal is blocked for charging a vehicle when it is established that a short circuit or defect is formed.

The self-test may be carried out at defined time intervals for a defined self-test time period to test the power electronics unit at a self-test voltage that corresponds to at least the maximum charging voltage of the charger. More particularly, the power electronics unit is subjected to this self-test voltage at the defined time intervals for the defined self-test time period when there is no motor vehicle connected to the charging terminal to interact with the power electronics unit for charging. The self-test voltage would cause a short circuit at certain semiconductor modules of the power electronics unit that are in a poor state, and this short circuit can be detected. The charging terminal then is blocked for charging a vehicle in the event of the formation of a short circuit at a respective power electronics unit. Only when no short circuit is formed at a power electronics unit during the self-test is the respective charging terminal enabled for subsequent charging of a vehicle. Thus, there is no risk that the traction battery of an electrically driven vehicle will be damaged during charging as a result of a short circuit at the power electronics unit of the charger.

Some embodiments perform the self-test by subjecting the power electronics unit to a self-test voltage that is greater than the maximum charging voltage of the charger to test the power electronics unit of the charger in a reliable manner.

Some embodiments terminate the self-test when a vehicle is being connected or is connected to the charging terminal during performance of the self-test. Thus, the traction battery of the electrically driven vehicle is not subjected to a risk of damage as a result of the self-test. In addition, charging with the desired voltage is made possible.

The self-test method of some embodiments includes checking the status of the respective power electronics unit. A self-test routine is allowed to begin only when the power electronics unit has no fault and is not charging. After a self-test routine has begun, a check is performed to ascertain whether a self-test currently is being performed at the respective power electronics unit. When no self-test currently is being performed at the respective power electronics unit, a check is performed to ascertain whether a time span since the last-performed self-test has reached or exceeded the defined time interval between self-tests. When it is established that the time span since the last-performed self-test has reached or exceeded the defined time interval between self-tests, a check is performed to ascertain whether the respective power electronics unit is sleeping or is operationally ready. A self-test is started when it is established that the respective power electronics unit is operationally ready. If it is established that the respective power electronics unit is sleeping, then the method includes waking up the respective power electronics unit and transferring the power electronics unit to an operationally ready state. This procedure determines whether a self-test routine should be started. If the respective power electronics unit that is intended to be subjected to a self-test should be in a sleep mode, the power electronics unit is awaken for the self-test.

According to some embodiments, a check takes place when a self-test is running to ascertain whether a vehicle is being connected to the respective charging terminal. When it is established that a vehicle is being connected to the respective charging terminal, the self-test is terminated and the defined charging voltage is provided at the respective charging terminal.

A check may take place when a self-test is running to ascertain whether the defined self-test time period for the self-test since the start of the self-test has been reached or exceeded. When it is established that the defined self-test time period for the self-test has been reached or exceeded, the self-test is ended.

The method of some embodiments includes monitoring a performance time for a self-test routine that has been started to determine whether a maximum self-test time period or performance time period for a self-test routine has been reached. The monitoring also may be carried out to ascertain whether, during the performance of the self-test routine, a vehicle is being connected to the charging terminal that is associated with the power electronics unit that is to be tested. The self-test may be terminated if a vehicle is being connected to the charging terminal. The self-test routine may be ended if the defined self-test time period for performing the self-test is reached or exceeded.

Embodiments of the invention are explained in more detail with reference to the drawings, without being limited to these exemplary embodiments.

### BRIEF DESCRIPTION OF THE DRAWINGS

FIG. 1 is a block circuit diagram of a first charger for electrically driven vehicles.

FIG. 2 is a block circuit diagram of a second charger for electrically driven vehicles.

FIG. 3 is a signal flow chart for illustrating the method for operating a charger for electrically driven vehicles.

### DETAILED DESCRIPTION

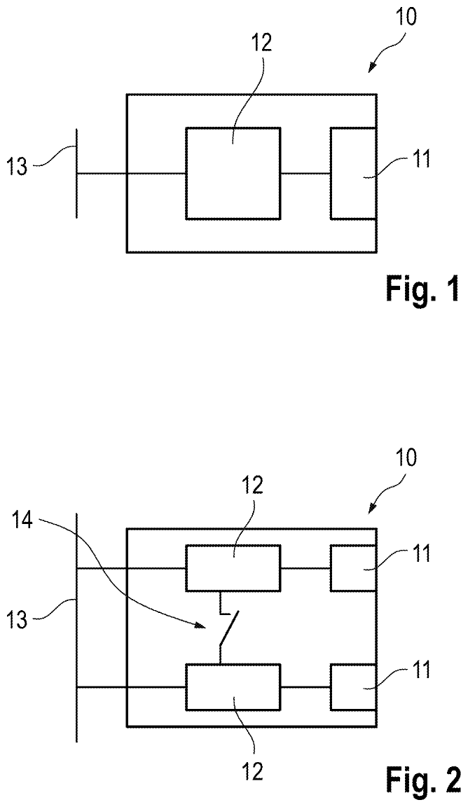

At the outset, it should be understood that the elements and functions described herein and shown in FIGS. 1-3 may be implemented in various forms of hardware, software or combinations thereof. These elements may be implemented in a combination of hardware and software on one or more appropriately programmed general-purpose devices, which may include a processor, memory and input/output interfaces. The term “connected” as used or implied herein mean directly connected to or indirectly connected with through one or more intermediate components. Such intermediate components may include both hardware and software-based components.

Those skilled in the art will appreciate that the Figures represent conceptual views of illustrative circuitry embodying the principles of the disclosure and/or also represent various processes that may be represented substantially in computer readable media and so executed by a computer or processor, whether or not such computer or processor is explicitly shown.

FIG. 1 schematically illustrates a bidirectional charger 10 for DC charging of an electrically driven vehicle. The charger 10 has a charging terminal 11 for connecting an electrically driven vehicle to be charged. The charging station 10 has a power electronics unit interacting with the charging terminal 11. The power electronics unit 12 comprises, for example, AC/DC converters, DC/DC converters and semiconductor modules and is connected to an electrical power supply system 13.

In the case of a bidirectional charger 10, starting from the electrical power supply system 13, electrical energy can be stored in the traction battery of an electrically driven vehicle, and electrical energy stored in the traction battery can be fed back into the electrical power supply system 13 for supporting the electrical power supply system 13.

FIG. 2 schematically shows a charger 10 with two charging terminals 11, and two electrically driven vehicles can be connected respectively to the two charging terminals 11. Two power electronics units 12 interact respectively with the charging terminal 11, and in turn link to an electrical power supply system 13 via the power electronics unit 12.

To increase the available charging power at one of the charging terminals 11 of the charger 10 shown in FIG. 2, it is possible to couple the two power electronics units 12 to one another via a switch 14. In this case only one of the charging terminals 11 is used for charging an electric vehicle at increased charging power.

The invention relates to a method and a control device for operating a bidirectional charger 10 for DC charging electrically driven vehicles. The charger 10 has at least one charging terminal 11 (in this embodiment two charging terminals 11) for connecting to an electrically driven vehicle and at least one power electronics unit 12 (in this embodiment two power electronic units 12) for providing a defined charging current and a defined charging voltage for DC charging at the respective charging terminal 11.

To perform a self-test of one of the power electronics unit 12 of one of the charging terminal 11, the respective power electronics unit 12 of the respective charging terminal 11 is subjected at defined time intervals to a self-test voltage that corresponds to at least the maximum charging voltage of the charger 10. For example, the self-test voltage may be applied every hour or every two hours, for a defined self-test time period, in particular for one minute, two minutes or three minutes.

In this case, a check is performed to ascertain whether a short circuit is formed at the respective power electronics unit 12, in particular at semiconductor modules of the respective power electronics unit 12 of the respective charging terminal 11. This check can take place, for example, via a current measurement, a voltage measurement or the like.

A charging terminal 11 is enabled for charging an electrically driven vehicle when it is established that no short circuit is formed at the respective power electronics unit 12.

On the other hand, the charging terminal 11 is blocked for charging an electric vehicle if a short circuit is determined to exist at the respective power electronics unit 12.

The self-test of the power electronics unit 12 is performed only when no vehicle is connected to the respective charging terminal 11 for a charging operation.

The self-test voltage applied to the power electronics unit 12 for performing the self-test preferably is greater than the maximum charging voltage of the charging station 10. In particular, the self-test voltage of some embodiments is greater than the maximum charging voltage of the charging station 10 by at least 50 V, preferably by at least 75 V, particularly preferably by at least 100 V.

The self-test of the power electronics unit 12 is terminated if, during the performance of the self-test, a vehicle is being connected to the charging terminal of the respective power electronics unit 12 that is being tested.

Within the meaning of the invention, the power electronics unit 12 of a bidirectional charger 10 for DC charging of electrically driven vehicles is subjected to a self-test voltage that corresponds to at least the maximum charging voltage of the charger, preferably is greater than this charging voltage, at defined time intervals for a defined self-test time period.

The self test will cause a short circuit at a semiconductor module of a power electronics unit 12 that is in a poor condition. The short circuit can be monitored in a conventional manner, for example via a current measurement, via a voltage measurement or via an insulation monitoring device.

A charging terminal 11 will be blocked for charging if the self test establishes a short circuit at the corresponding power electronics unit 12. The charging terminal 11 will be enabled for electrical charging of a motor vehicle only when the self test establishes that no short circuit is established at the corresponding power electronics unit 12.

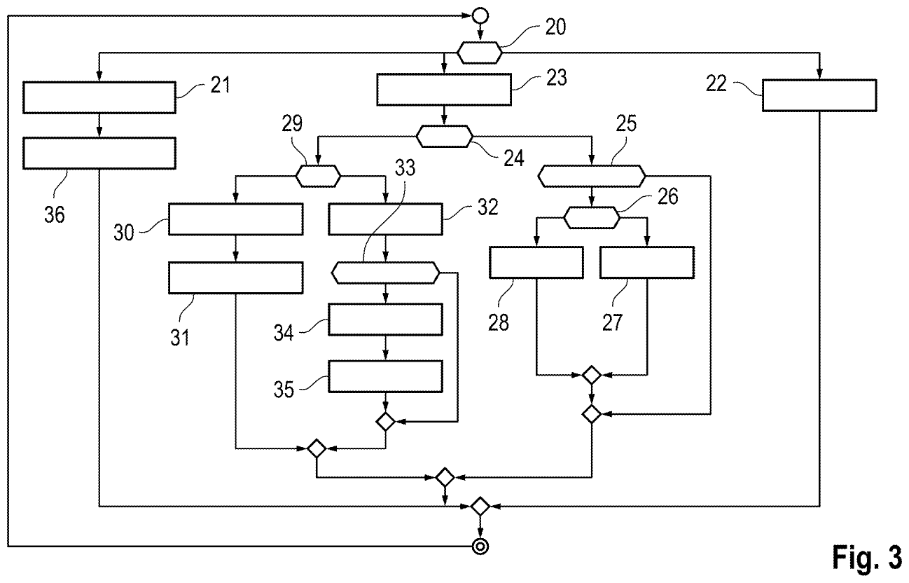

A self-test at a power electronics unit 12 is performed by the method illustrated by the flow chart of FIG. 3. The method of this embodiment starts at block 20 by determining the status of the power electronics unit 12 being checked or interrogated. The method proceeds to block 21 if the power electronics unit 12 is determined to have a fault status; or proceeds to block 22 if the power electronics unit 12 is determined to have a charging status; or proceeds to block 23 if the power electronics unit 12 is determined to have a ready-to-charge status.

A self-test routine does not begin if the respective power electronics unit 12 has the fault status of block 21 or the charging status of block 22. A self-test routine begins only when it is established in block 20 that the respective power electronics unit 12 assumes or has the ready-to-charge status of block 23. In the event of the presence of the fault status, in a block 36 a corresponding error code is generated and sent, for example to a display of the charging station 10.

After the self-test routine has begun, a check is performed in a block 24 to ascertain whether or not a self-test currently is being performed at the respective power electronics unit 12. If it is established in block 24 that no self-test routine currently is being performed at a power electronics unit 12 for which the ready-to-charge status was previously established, there is a branching off from block 24 to block 25.

In block 25, a check is performed to ascertain whether a time span since the last-performed self-test has reached or exceeded the defined time interval between two self-tests, for example, a time span of one hour or two hours.

If it is established in block 25 that the time span since the last-performed self-test has reached or exceeded the defined time interval between two successive self-tests, then a check is performed in a block 26 to ascertain whether the respective power electronics unit is sleeping or is operationally ready. If it is established in block 26 that the respective power electronics unit is sleeping, there is a branching off from block 26 to block 27. In block 27, the respective power electronics unit 12 is woken up and transferred to an operationally ready state.

If, on the other hand, it is established in block 26 that the respective power electronics unit is operationally ready and is not sleeping, there is a branching off to block 28, wherein a self-test is started in block 28.

If it is established in block 24 that a self-test currently is being performed at the power electronics unit 12, there is a branching off from block 24 to block 29. A check is performed in block 29 to ascertain whether a vehicle is connected or is being connected to the charging terminal 11 interacting with the power electronics unit 12.

There is a branching off to block 30 if it is established in block 29 that a motor vehicle is connected or is being connected to the respective charging terminal 11. The voltage provided at the respective power electronics unit 12 then is limited to the maximum charging voltage. The self-test subsequently is terminated in block 31.

If, on the other hand, it is established in block 29 that there is no vehicle connected or being connected to the charging terminal interacting with the power electronics unit 12, there is a branching off from block 29 to block 32, and the power electronics unit 12 is subjected to the self-test voltage that is greater than the maximum charging voltage of the charger 10.

After the self-test in block 32, a check is performed in block 33 to ascertain whether the defined self-test time period for the self-test has been reached or exceeded. If the check at block 33 determines that the time period for the self-test is reached or exceeded, then there is a branching off from block 33 to block 34, and the voltage at the power electronics unit 12 is limited to the maximum charging voltage of the charger again. Then, the self-test is ended in a block 35.

As described with reference to FIG. 3, the status of the power electronics unit to be tested is checked in block 20. Nothing is undertaken if the power electronics unit 12 has the fault status of block 21 or the charging status of block 22. Only a corresponding error code is generated and sent in block 36. If it is established in block 20 that the power electronics unit 12 has the ready-to-charge status of block 23, a check is performed in block 24 to ascertain whether a self-test currently is being performed. If a self-test is not currently being performed, then a check is performed in block 25 to ascertain whether the defined time between two self-tests has been reached or exceeded. If this is the case, then either a sleeping power electronics unit is woken up in block 27, or a self-test is started in block 28. After block 27 or block 28, and after it is established in block 25 that the defined time interval between two self-tests has not yet been reached or exceeded, the method of FIG. 3 starts from the beginning. If it is established in block 24 that a self-test currently is being performed at a power electronics unit 12, a check is performed in block 29 to ascertain whether a motor vehicle is connected or is being connected to the respective charging terminal 11. If this is the case, there is a branching off from block 29 to block 30 and subsequently to block 31, then the self-test is terminated and the voltage at the charging terminal 11 is limited to the maximum charging voltage. The charging voltage required for charging is provided at the charging terminal 11, and the method in FIG. 3 begins from the start. If, on the other hand, it is established in block 29 that there is no vehicle connected to the corresponding charging terminal 11, the power electronics unit is subjected in block 32 to the self-test voltage, which is greater than the maximum charging voltage. In this case, a check is performed continuously in block 33 to ascertain whether the defined self-test time period for the self-test has been reached or exceeded. If the defined self-test time period for the self-test has been exceeded, the self-test is ended in blocks 34, 35, and the method begins again from the start.

The invention also relates to a control device of a bidirectional charger 10 for electrical DC charging of electrically driven vehicles. The control device is designed to perform automatically the above-described method.

In addition, the invention relates to a charger with such a control device.

1. A method for operating a bidirectional charger (10) for DC charging of electrically driven vehicles, the charger (10) having at least one charging terminal (11) for connecting to an electrically driven vehicle and at least one power electronics unit (12) for providing a defined charging current and a defined charging voltage at the respective charging terminal (11), the method comprising:
checking whether a vehicle is connected to the charging terminal (11);
performing a self-test by subjecting the power electronics unit (12) of the charging terminal (11) to a self-test voltage equal to at least a maximum charging voltage of the charger (10) at defined time intervals for a defined self-test time period;
ascertaining whether a short circuit or defect is formed at the power electronics unit (12) of the charging terminal (11);
enabling the charging terminal (11) to charge a vehicle if it is established that no short circuit or defect is formed; and
blocking the charging terminal (11) for charging a vehicle if it is established that a short circuit or defect exists.

2. The method of claim 1, wherein the self-test voltage is greater than the maximum charging voltage of the charger (10).

3. The method of claim 2, wherein the self-test voltage is greater than the maximum charging voltage of the charger (10) by at least 50 volts.

4. The method of claim 1, further comprising terminating the self-test of the power electronics unit (11) if a vehicle is being connected to the charging terminal (11) during the performance of the self-test.

5. The method of claim 1, wherein performing the self-test, comprises:
checking the power electronics unit (12) to determine whether the power electronics unit has a fault status or a charging status, and beginning a self-test only upon determining that that no fault status or charging status exists;
checking whether the self-test is still being performed at the power electronics unit after having begun the self-test;
if no self-test currently is being performed at the power electronics unit, checking whether a time span since a last-performed self-test has reached or exceeded a defined time interval between self-tests;
if the time span since the last-performed self-test has reached or exceeded the defined time interval between self-tests, checking whether the respective power electronics unit is sleeping or is operationally ready; and
starting a self-test upon determining that the respective power electronics unit is operationally ready.

6. The method of claim 5, wherein if the power electronics unit is determined to be sleeping, the method further comprising waking up the power electronics unit and establishing an operationally ready state.

7. The method of claim 5, further comprising:
determining whether a vehicle is being connected to the charging terminal; and
terminating the self-test and providing the defined charging voltage at the respective charging terminal (11) upon determining that a vehicle is being connected to the respective charging terminal.

8. The method of claim 5, further comprising:
when a self-test is performed, checking whether the defined self-test time period for a self-test since the start of the self-test has been reached or exceeded; and
when it is established that the defined self-test time period has been reached or exceeded, ending the self-test.

9. A control device of a bidirectional charger (10) for DC charging of electrically driven vehicles, wherein the control device is configured to automatically perform the method of claim 1.

10. A charger for bidirectional charging of electrically driven vehicles having the control device of claim 9.
